(19) United States
(12) Patent Application Publication
(10) Pub. No.: US 2009/0169344 A1
(43) Pub. Date: Jul. 2, 2009

(54) Substrate processing apparatus and substrate processing method

(75) Inventors: Toshihisa Nozawa, Amagasaki-shi (JP); Satoru Kawakami, Nirasaki-shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(73) Assignee: Tokyo Electron Limited

(21) Appl. No.: 12/379,767

(22) Filed: Feb. 27, 2009

Related U.S. Application Data
(63) Continuation of application No. 10/786,068, filed on Feb. 26, 2004.

(30) Foreign Application Priority Data
Feb. 27, 2003 (JP) 2003-052082
Sep. 1, 2003 (JP) 2003-309428

(51) Int. Cl. H01L 21/677

(52) U.S. Cl. 414/221; 414/222.12; 414/222.02

(57) ABSTRACT

A substrate processing apparatus 1 has: sensors 21 and 22 provided in an etching chamber 14 and configured to detect a relative position between the etching chamber 14 and a wafer transfer mechanism 23; a control section 38 configured to correct positional displacement; a motor controller 39; a motor 28; and a motor 30. Since the positional displacement of a wafer W can be corrected, the wafer transfer mechanism 23 is capable of carrying the wafer W into the etching chamber 14 without causing any positional displacement, so that the wafer W can be placed on a susceptor 19 at a proper position.

### CROSS REFERENCE TO RELATED APPLICATIONS

This application is based upon and claims the benefit of priority from the prior Japanese Patent Application No. 2003-052082, filed on Feb. 27, 2003 and the prior Japanese Patent Application No. 2003-309428, filed on Sep. 1, 2003; the entire contents of which are incorporated herein by reference.

### BACKGROUND OF THE INVENTION

1. Field of the Invention

The present invention relates to a substrate processing apparatus and a substrate processing method for applying processing such as plasma CVD (Chemical Vapor Deposition) and etching on a substrate, for example, a semiconductor wafer or the like.

2. Description of the Related Art

A semiconductor device fabricating process includes many steps, and main steps for forming a circuit pattern on, for example, a semiconductor wafer (hereinafter, referred to as a wafer) include a cleaning step of cleaning the wafer, a film deposition step of forming a metal film and an insulating film, a photolithography step of forming a wiring pattern, using a photoresist, an etching step of etching the wafer on which a resist pattern is formed, and other steps such as a step of injecting impurities.

In a case where the above-mentioned etching step uses, for example, plasma and in a case where a process in the film deposition step is conducted by, for example, a CVD unit, the wafer is carried into a vacuum chamber and is processed in this chamber.

Such a vacuum processing system is provided with a pre-alignment unit in which, for example, the wafer is pre-aligned before carried into each processing unit in which the wafer is to be processed. In such a system, a plurality of, for example, plasma processing units and so on are disposed adjacent to one another as processing units, and the wafer, after being aligned in the pre-alignment unit, is carried into each of the processing units by a transfer mechanism to undergo a predetermined process. Such a system is disclosed in, for example, Japanese Patent Laid-open Application No. Hei 10-154705 ([0002] and FIG. 3) and so on.

In the vacuum processing system as configured above, the wafer is transferred to the first processing unit after being aligned in the pre-alignment unit. Therefore, when the wafer is transferred to the first processing unit, the alignment has been already made. However, there has been such a problem that, if the wafer does not go through the pre-alignment unit before transferred from the first processing unit to a subsequent processing unit, the wafer is not aligned, resulting in positional displacement. Moreover, there has been a demand for enhancement in transfer efficiency to improve process efficiency.

### SUMMARY OF THE INVENTION

The present invention is made under such circumstances, and an object thereof is to provide a substrate processing apparatus and a substrate processing method that makes it possible to carry a substrate into a process chamber without causing any positional displacement of the substrate. Another object of the present invention is to enhance transfer efficiency to improve process efficiency.

In order to solve the problems stated above, a substrate processing apparatus according to a main aspect of the present invention includes: a first process chamber in which a first process disposes a substrate; a second process chamber in which a second process disposes the substrate that has finished the first process a transfer mechanism configured to transfer the substrate and carry the substrate into and out of the first process chamber and the second process chamber; a detecting mechanism configured to detect a relative position between the substrate to be carried into the second process chamber by the transfer mechanism and the second process chamber; and a correcting mechanism configured to correct displacement of the relative position based on a result of the detection by the detecting mechanism.

Since the substrate processing apparatus as configured above has the detecting mechanism configured to detect the relative position to the second process chamber and the correcting mechanism configured to correct the displacement of the relative position based on the result of the detection by the detecting mechanism, it is possible to carry the substrate into the second process chamber without causing any positional displacement of the substrate. In the prior art, on the other hand, the positional displacement sometimes occurs when a substrate is transferred from a first process chamber to a second process chamber although no positional displacement occurs in the first process chamber into which the substrate is first carried since the substrate is carried theretino after being aligned by, for example, pre-alignment or the like.

According to one form of the present invention, the transfer mechanism has a holding portion configured to hold the substrate, and the detecting mechanism detects an absolute position of the holding portion to the second process chamber. Thus detecting the absolute position of the holding portion to read the absolute position of the substrate held by the holding portion can facilitate the correction of the positional displacement.

According to one form of the present invention, the substrate processing apparatus further includes: a storage unit configured to store a coordinate system for representing the absolute position of the holding portion and predetermined coordinates representing a proper position of the holding portion in the coordinate system, and the correcting mechanism compares coordinates in the coordinate system of the substrate detected by the detecting mechanism and the predetermined coordinates to correct displacement between the both coordinates, thereby correcting the displacement of the relative position. Thus comparing the two coordinates to calculate an amount of the positional displacement can facilitate the correction of the positional displacement.

According to one form of the present invention, the detecting mechanism has at least two photosensors provided on a carry-in route of the substrate by the transfer mechanism, and an interval between the two photosensors is smaller than a diameter of the substrate. When the interval between the two photosensors is smaller than the diameter of the substrate, the substrate, when being carried in, passes through detection areas of the two sensors, so that the positional displacement of the substrate can be detected when the substrate is carried in.

According to one form of the present invention, the carry-in route of the substrate by the transfer mechanism extends linearly, and the two photosensors are arranged in a direction substantially orthogonal to the carry-in route. Such arrangement of the two photosensors in the direction substantially orthogonal to the carry-in route of the substrate can facilitate the detection and correction of the positional displacement when position coordinates being orthogonal coordinates are used.

According to one form of the present invention, the detecting mechanism has a transmission-type photosensor. The use of a reflection-type photosensor among photosensors might cause defective sensitivity due to variation in reflection coefficients depending on films formed on the substrate. On the other hand, the use of the transmission-type photosensor enables reliable detection irrespective of the reflection coefficient.

A substrate processing method according to a main aspect of the present invention is a substrate processing method of a substrate processing apparatus including: a first process chamber in which a first process disposes a substrate; a second process chamber in which a second process disposes the substrate; and a transfer mechanism configured to transfer the substrate and carry the substrate into and out of the first process chamber and the second process chamber, the method including:

(a) applying the first process on the substrate in the first process chamber;

(b) carrying the substrate out of the first process chamber by the transfer mechanism after the step (a);

(c) carrying the substrate, which is carried out of the first process chamber, into the second process chamber by the transfer mechanism;

(d) detecting a relative position between the substrate to be carried into the second process chamber by the transfer mechanism in the step (c) and the second process chamber; and

(e) correcting displacement of the relative position based on a result of the detection of the step (d).

According to the substrate processing method as configured above, it is possible to carry the substrate into the second process chamber at a proper position without causing any positional displacement when the substrate is transferred from the first process chamber to the second process chamber.

According to one form of the present invention, the step (d) is conducted in the course of carrying the substrate into the second process chamber in the step (c). This makes it possible to prevent the positional displacement of the substrate while inhibiting decrease in process efficiency.

A substrate transfer device according to a main aspect of the present invention includes: a base portion; at least two holding portions each capable of holding a substrate; an arm portion coupling the at least two holding portions to each other and connected to the base portion; and a driving portion configured to drive the arm portion, thereby driving the at least two holding portions to move back and forth synchronously.

Another substrate transfer device according to a main aspect of the present invention includes: a base portion; two holding portions each capable of holding a substrate; an arm portion coupling the two holding portions to each other and connected to the base portion; and a driving portion configured to drive the arm portion, thereby driving the two holding portions to move back and forth so as to become apart from and close to each other.

Still another substrate transfer device according to a main aspect of the present invention includes: a base portion; and a plurality of transfer mechanisms provided on the base portion, each of the transfer mechanisms including: two holding portions each capable of holding a substrate; an arm portion coupling the two holding portions to each other and connected to the base portion; and a driving portion configured to drive the arm portion, thereby driving the two holding portions to move back and forth so as to become apart from and close to each other.

According to the substrate transfer device as configured above, substantially simultaneous access to a plurality of process chambers disposed, for example, around the substrate transfer device is possible, so that the substrate can be efficiently transferred, resulting in improved process efficiency.

### BRIEF DESCRIPTION OF THE DRAWINGS

FIG. 1 is a plane view showing the configuration of a substrate processing apparatus according to a first embodiment of the present invention.

FIG. 2 is a side view showing the substrate processing apparatus according to the first embodiment of the present invention.

FIG. 3 is a plane view showing the structure of an X-Y jointed-arm robot shown in FIG. 1.

FIG. 4 is a cross-sectional view of the X-Y jointed-arm robot shown in FIG. 1.

FIG. 5 is a plane view showing the positional relationship between a transfer mechanism and an etching chamber.

FIG. 6 is a plane view showing the relative positional relationship between the proper position of a wafer and the position of a wafer that is displaced.

FIG. 7 is a plane view for explaining the center of the wafer at the proper position.

FIG. 8 is a plane view showing the configuration of a substrate processing apparatus according to a second embodiment of the present invention.

FIG. 9A and FIG. 9B are plane views of a wafer transfer mechanism used in the substrate processing apparatus shown in FIG. 8.

FIG. 10A and FIG. 10B are side views of the wafer transfer mechanism used in the substrate processing apparatus shown in FIG. 8.

FIG. 11 is a plane view showing another embodiment of the wafer transfer mechanism.

FIG. 12 is a side view showing the wafer transfer mechanism shown in FIG. 11.

FIG. 13 is a plane view showing the state in which the wafer transfer mechanism shown in FIG. 11 is used in a substrate processing apparatus according to another embodiment.

FIG. 14 is a plane view showing a wafer transfer mechanism according to still another embodiment.

### DESCRIPTION OF THE EMBODIMENTS

Hereinafter, embodiments of the present invention will be explained with reference to the drawings.

### First Embodiment

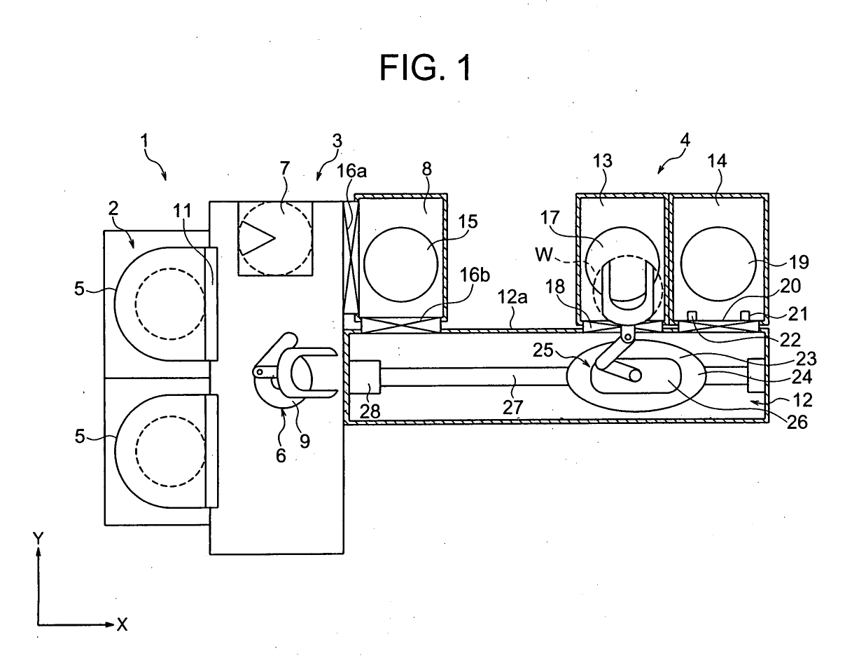

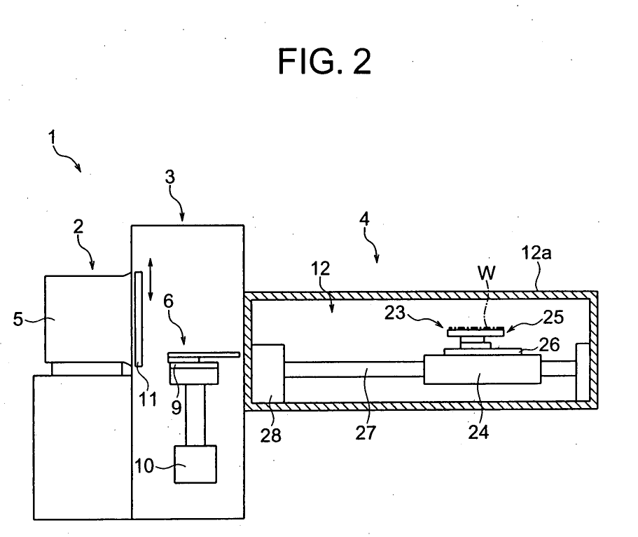

FIG. 1 is a plane view showing the configuration of a substrate processing apparatus according to a first embodiment of the present invention, and FIG. 2 is a side view thereof.

This substrate processing apparatus 1 is composed of a cassette mounting table 2, a transfer chamber 3, and a vacuum process section 4, which are arranged linearly in an X direction in the drawing.

A plurality of (for example, two) cassettes 5 are arranged on the cassette mounting table 2 in line in a Y direction in the drawing. An example of the cassette 5 is a FOUP (Front Opening Unified Pod) having sealability in which a plurality of (for example, 25) wafers W are housed, being arranged in multiple tiers.

In the transfer chamber 3, a wafer transfer mechanism 6, which is constituted of a jointed-arm robot, and a pre-alignment stage 7 are provided. The wafer transfer mechanism 6 takes out the wafer W from the cassette 5 to place the wafer W on the pre-alignment stage 7, and thereafter, loads the wafer W into a load lock chamber 8 disposed on a vacuum process section 4 side. The wafer transfer mechanism 6 also takes out the wafer W from the load lock chamber 8 to put it in the cassette 5. The wafer transfer mechanism 6 is configured to be rotatable in a horizontal plane (in a θ direction) by a base portion 9. As shown in FIG. 2, the wafer transfer mechanism 6 is also configured to be movable up/down by an amount corresponding to the height of the cassette 5 by a motor 10. The pre-alignment stage 7 has a function of aligning the wafer W direction-wise in the horizontal plane.

Incidentally, a 2-link jointed-arm robot is adopted as the wafer transfer mechanism 6 in this embodiment, but, for example, a 1-link jointed-arm robot may be adopted according to necessary stroke.

Further, the transfer chamber 3 has an openable/closable (openable/closable, for example, vertically) shutter 11 provided in front of the cassette 5. This shutter 11 allows the wafer transfer mechanism 6 to access the cassettes 5. Further, the downflow of N₂ gas is formed under the atmospheric pressure in the transfer chamber 3.

The vacuum process section 4 has a transfer path 12 extending linearly along the X direction in the drawing. One end of the transfer path 12 is adjacent to the transfer chamber 3. The load lock chamber 8, a CVD chamber 13, and an etching chamber 14 are arranged on one side of the transfer chamber 12 along the transfer path 12 in sequence from the transfer chamber 3 side. Further, the transfer path 12 is enclosed in a case 12a, and it is possible to bring the inside of the case 12a into a vacuum state when the pressure thereof is reduced by a not-shown vacuum pump.

A wafer mounting table 15 on which the wafer W is to be placed is provided substantially at the center of the load lock chamber 8. The load lock chamber 8 is connected to the transfer chamber 3 via a gate valve 16a, and also connected to the transfer path 12 via a gate valve 16b.

A susceptor 17 on which the wafer W is mounted and held when the wafer W is processed is provided substantially at the center of the CVD chamber 13. For example, a plurality of stick-shaped lifter pins which are not shown are provided on the susceptor 17 to stand vertically from a holding face thereof and a not-shown driving mechanism enables these lifter pins to move up and down. Via these lifter pins, the wafer W is delivered to/from the susceptor 17 from/to a wafer transfer mechanism 23. The CVD chamber 13 is connected to the transfer path 12 via a gate valve 18. Incidentally, the lifter pins may be fixed and the susceptor 17 may be configured to be hoistable/lowerable relative to the lifter pins.

A susceptor 19 on which the wafer W is mounted and held when the wafer W is processed is provided substantially at the center of the etching chamber 14. Lifter pins whose function and intended use are the same as those of the lifter pins in the CVD chamber 13 are provided on this susceptor 19. The etching chamber 14 is connected to the transfer path 12 via a gate valve 20. Further, two sensors 21, 22 are disposed in the etching chamber 14, being positioned on both sides of the gate valve 20 respectively. These sensors 21, 22 are intended for detecting the positional displacement of the wafer W. A method of detecting the positional displacement of the wafer W will be described later.

The wafer transfer mechanism 23 linearly movable along the X direction is provided in the transfer path 12. The wafer transfer mechanism 23 has a stage 24 linearly movable along the X direction. The stage 24 is configured to be moved by a motor 28 along a rail 27 in the X direction. As a driving mechanism thereof, for example, a belt-driving mechanism or the like is adoptable. For example, a 1-link, X-Y jointed-arm robot 25 is disposed as a transfer robot on the stage 24.

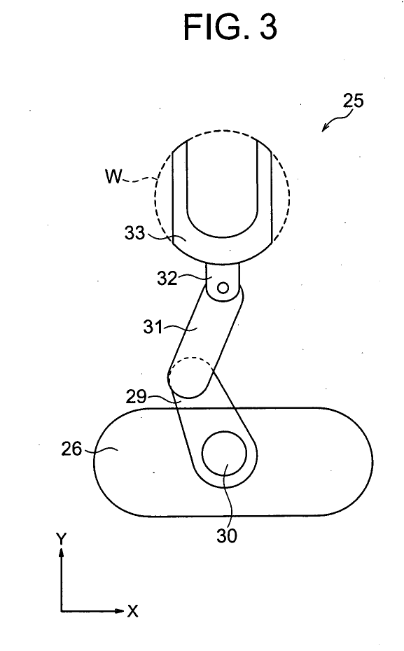

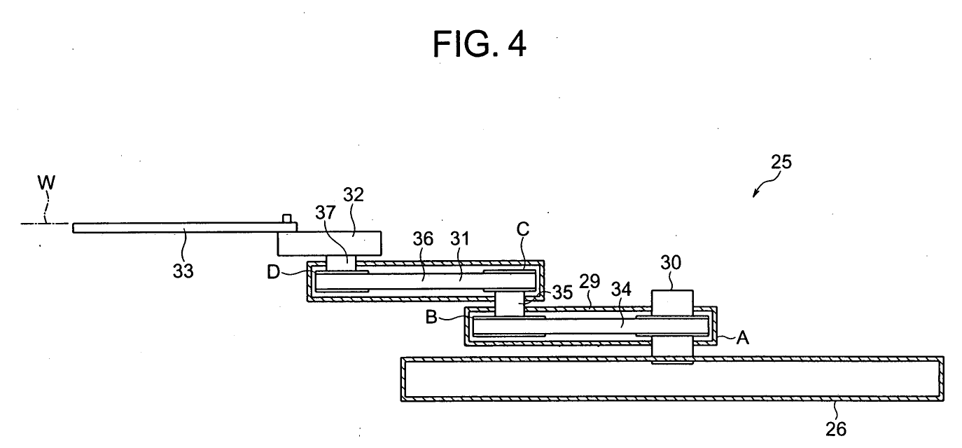

FIG. 3 is a plane view showing the structure of the X-Y jointed-arm robot 25, and FIG. 4 is a cross-sectional view thereof.

A first arm 29 rotatable by a motor 30 is provided on a base 26 of the X-Y jointed-arm robot 25. A second arm 31 is connected to the first arm 29 at one end and is connected to a support plate 32 at the other end. Tweezers 33 to hold a wafer W are fixed to the support plate 32. The tweezers 33 have, for example, a plurality of suction pads (not shown) as a mechanism to hold the wafer W.

A pulley A fixed to a rotation shaft of the motor 30 is provided at one end of the first arm 29. The rotation of the motor 30 is transmitted via the pulley A and a belt 34 to a pulley B provided at the other end of the first arm 29. The rotation of the pulley B is transmitted via a shaft member 35 to a pulley C fixed in the second arm 31. The rotation of the pulley C is transmitted to a pulley D via a belt 36. The rotation of the pulley D is transmitted via a shaft member 37 to the support plate 32 fixed to the shaft member 37 so that the tweezers 33 are moved back and forth linearly (in a Y direction).

Such a structure of the X-Y jointed-arm robot 25 enables the tweezers 33 to move back and forth in one-axial direction, namely, in the Y direction shown in FIG. 1.

Next, the positional relationship between the etching chamber 14 and the wafer transfer mechanism 23 will be explained.

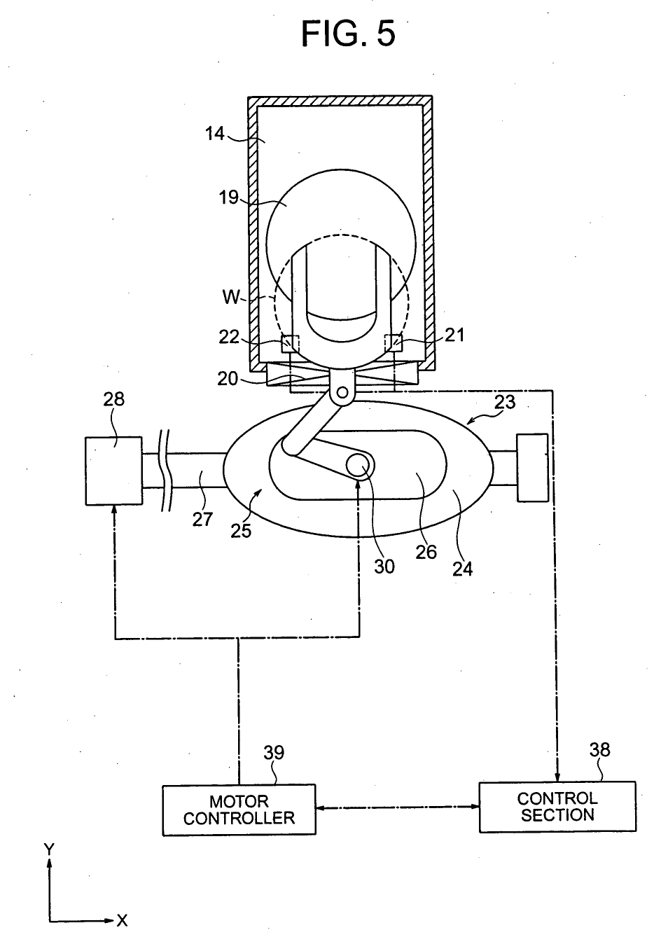

FIG. 5 is a plane view showing the positional relationship between the wafer transfer mechanism 23 and the etching chamber 14, in which portions not necessary for explanation here are omitted.

As shown in FIG. 5, the sensors 21, 22 are arranged in a direction substantially orthogonal to a carry-in route along which the wafer W is carried in from the gate valve 20 toward the wafer susceptor 19. The sensors 21 and 22 are disposed at a smaller interval than the diameter of the wafer W, and they are configured to detect the positional displacement from a proper position of the wafer W when the wafer W passes through these sensors 21 and 22. These sensors 21 and 22 are, for example, photosensors, and for example, of a transmittance type. Each of the transmittance-type photosensors 21 and 22 has one light emitting portion and one light receiving portion, though not shown, which are arranged in a vertical direction, and light from the light emitting portion is received in the light receiving portion. The use of reflection-type photosensors here might cause defective sensitivity due to variation in reflection coefficient depending on films formed on the wafer W, and therefore, the use of the transmittance-type photosensors is preferable.

These sensors 21 and 22 detect values of Ya, Yb , which will be described later, from the wafer W that has passed therethrough to send these values to a control section 38. The control section 38 calculates the displacement from the proper position based on these values of Ya, Yb. Calculated values are sent to a motor controller 39, and the positional displacement of the wafer W is corrected under the control over each of the motors 28, 30 by the motor controller 39.

Next, the operation of the substrate processing apparatus 1 as configured above will be explained.

First, the shutter 11 opens, and the wafer transfer mechanism 6 accesses the cassette 5 to take out one of the wafers W. The wafer W that has been taken out is carried into the pre-alignment stage 7 to be pre-aligned. Thereafter, the wafer transfer mechanism 6 takes out the wafer W from the pre-alignment stage 7 to carry it into the load lock chamber 8. In this case, the wafer transfer mechanism 6 accesses the mounting table 15 to place the wafer W thereon.

In the load lock chamber 8, the wafer W is placed on the mounting table 15 to be kept on standby thereon. Thereafter, the gate valve 16a is closed, and a not-shown vacuum pump exhausts the inside of the load lock chamber 8 to vacuum. This vacuum exhaust is conducted until the pressure reaches the same pressure as that of the inside of, for example, the transfer path 12, the CVD chamber 13, and the etching chamber 14 (for example, 20 Pa to 1330 Pa (about 0.1 Torr to about 10 Torr)).

When the pressure inside the load lock chamber 8 reaches 20 Pa to 1330 Pa, the gate valve 16b is opened, and the X-Y jointed-arm robot 25 takes out the wafer W placed on the mounting table 15 to carry the wafer W into the CVD chamber 13.

Then, when a CVD process in the CVD chamber 13 is finished, the gate valve 18 opens. Next, the X-Y jointed-arm robot 25 accesses the CVD chamber 13 to take out the wafer W.

Further, the wafer W that has been taken out is carried into the etching chamber 14. The sensors 21 and 22 are used when the wafer W is carried in so that the positional displacement of the wafer W is corrected. In this etching chamber 14, the wafer W is etchbacked so that the surface of a metal film formed by the CVD process is planarized.

When the etchback process in the etching chamber 14 is finished, the gate valve 20 opens. Next, the X-Y jointed-arm robot 25 accesses the etching chamber 14 to take out the wafer W. It further carries the wafer W that has been taken out into the load lock chamber 8 to place the wafer W on the mounting table 15.

When the pressure inside the load lock chamber 8 is made slightly higher than the atmospheric pressure after the wafer W is placed on the mounting table 15, the gate valve 16a is opened so that the inside of the load lock chamber 8 is made open to the atmosphere. In this manner, the flow of particles into the load lock chamber 8 can be prevented.

Thereafter, the wafer transfer mechanism 6 takes out the wafer W from the mounting table 15 in the load lock chamber 8 to return the wafer W to the cassette 5.

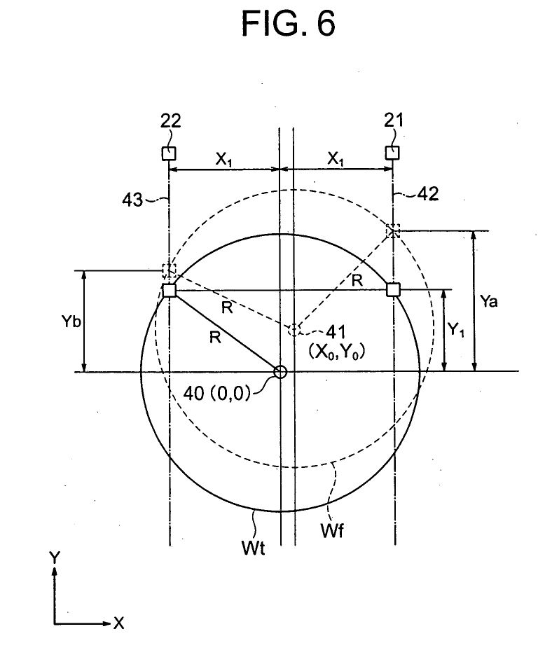

The operation when the wafer W is carried into the etching chamber 14, among the above-described operations of the substrate processing apparatus 1, will be especially explained, using FIG. 5 and FIG. 6.

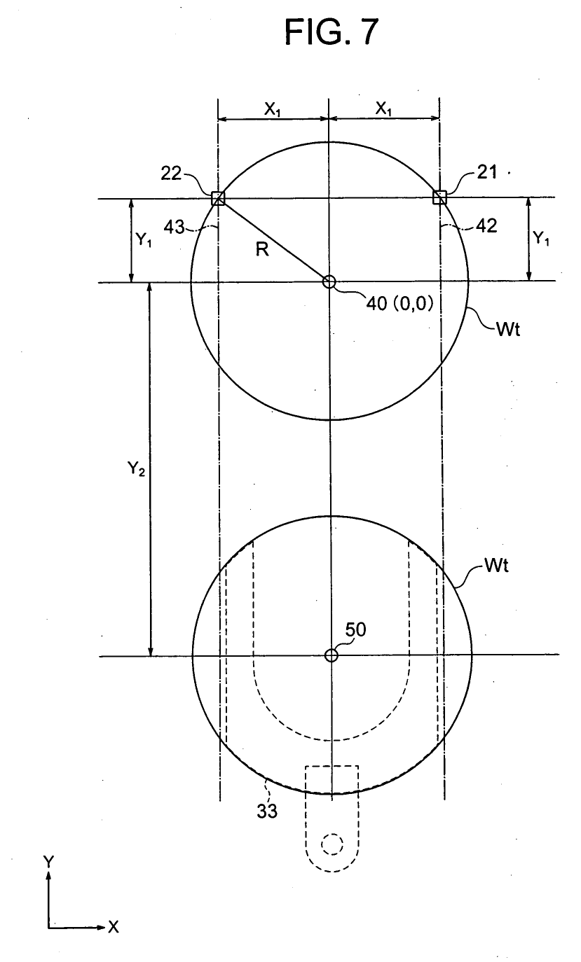

FIG. 6 is a plane view showing the relative positional relationship between the proper position of the wafer W and the position of the wafer W that is displaced. FIG. 7 is a plane view showing the wafer W at the proper position.

In FIG. 6 and FIG. 7, the wafer W shown by the solid line at the proper position is defined as a proper wafer Wt and the center thereof is defined as a proper center 40. Further, the wafer W shown by the broken line that is displaced is shown as a displaced wafer Wf and the center thereof is defined as a displaced center 41. Lines 42 and 43 show traces of the sensors 21 and 22 through which the wafer W passes. A coordinate system for determining the absolute positions of the wafer W and the tweezers 33 is provided, the proper center 40 being defined as the origin (0, 0). This coordinate system proves to be an effective coordinate system for determining the position relative to what is installed fixedly such as the CVD chamber 13 and the etching chamber 14.

A case where the wafer Wt is carried into the etching chamber 14 while being kept at the proper position will be explained with reference to FIG. 7.

For example, the wafer transfer mechanism 23 moves in an X axis direction while holding the wafer Wt (see FIG. 1 or FIG. 5), so that the wafer Wt is transferred in front of the etching chamber 14, where the movement thereof is tentatively stopped. The wafer Wt shown in the lower part in FIG. 7 shows the stopped state thereof. The center of the wafer Wt at this stop position is denoted by the reference numeral 50. The tweezers 33 move in the Y direction from this stop position while holding the wafer Wt. The wafer Wt shown in the upper part in FIG. 7 is the wafer Wt at the instant when its existence is detected by the sensors 21 and 22. The center of the wafer Wt at the instant when the sensors 21, 22 detect the existence of the wafer Wt is defined as the proper center 40 as described above. The distances in the Y direction and in the X direction from the proper center 40 to the sensors 21 and 22 are defined as Y1 and X1 respectively. A distance Y2, for example, from a center 50 to the center 40 when the wafer Wt is moved is determined in advance, and the distance Y2 can be calculated based on the number of rotation pulses of the motor 30 of the wafer transfer mechanism 23.

Hereinafter, a wafer that is displaced will be explained with reference to FIG. 6, assuming this wafer is the wafer Wf.

The movement of the wafer transfer mechanism 23 in the X axis direction causes the wafer Wf to be transferred in front of the etching chamber 14, where the movement thereof is tentatively stopped. The wafer transfer mechanism 23 carries the displaced wafer Wf placed on the tweezers 33 into the etching chamber 14. The displaced wafer Wf, when being carried in, passes between the light emitting portion and the light receiving portion of each of the sensors 21 and 22. Here, if the wafer Wf is displaced as shown in FIG. 6, the sensor 21 first detects the wafer Wf, and the sensor 22 thereafter detects the wafer Wf. The coordinates of the wafer Wf thus detected by the sensors 21 and 22 at different timings are defined as Ya and Yb respectively.

As described above, the distance Y2 and the number of rotation pulses corresponding to the distances Y2 are determined in advance. Therefore, based on the distance Y2 and the number of rotation pulses corresponding to Y2 as a reference, the values of Ya and Yb can be calculated from differences thereof from the reference. Specifically, when the wafer Wf is displaced as shown in FIG. 6, the sensor 21 detects the wafer wf at a timing before the reference (at a position where the number of rotation pulses does not reach the reference), and the sensor 22 detects the wafer Wf at a timing after the reference (at a position where the number of rotation pulses exceeds the reference).

The control section 38 receives these values Ya and Yb from the sensors 21 and 22 respectively. The control section 38 calculates the displacement of the relative position between the proper center 40 and the displaced center 41 based on these values Ya and Yb (calculation formulas used here will be described later). The control section 38 sends the calculated values to the motor controller 39 and the calculated values are further sent from the motor controller 39 to the respective motors 28 and 30. The motor 28 moves the wafer transfer mechanism 23 by an amount corresponding to a positional displacement X0 in the X axis direction, and the motor 30 moves the tweezers 33 by an amount corresponding to a positional displacement Y0 in the Y-axis direction. Thus, the wafer W is put at the corrected proper position to be mounted on the susceptor 19 at a proper position.

The aforesaid calculation formulas will be explained.

With the proper center 40 being defined as the origin (0, 0) and the displaced center 41 being defined as (X0, Y0), the displaced center 41 (X0, Y0) is calculated. Here, the radius of the wafer W is defined as R. The values of Ya, Yb detected by the sensors 21 and 22 are substituted in the following formulas (1) and (2), so that X0 and Y0 can be calculated. In other words, the displaced center 41 (X0, Y0) can be calculated. This gives the displacement in the X axis direction as X0, and therefore, the correction in the X axis direction can be made by the movement by −X0. The displacement in the Y axis direction is given as Y0, and therefore, the correction in the Y axis direction can be made by the movement by −Y0.

(X1−X0)²+(Ya−Y0)²=R² (1)

(X1+X0)²+(Yb−Y0)²=R² (2)

As described above, in this embodiment, since the positional displacement of the wafer W can be corrected, the wafer transfer mechanism 23 is capable of carrying the wafer W into the etching chamber 14 without causing any positional displacement, so that it is capable of placing the wafer W on the susceptor 19 at the proper position.

Conventionally, the positional displacement is sometimes caused when the wafer W is transferred to the etching chamber 14 from the CVD chamber 13. In this embodiment, on the other hand, in the CVD chamber 13 into which the wafer W is first carried, the wafer W that has been aligned by pre-alignment or the like is carried in, and in the etching chamber 14, the positional displacement is corrected by the sensors 21, 22. Consequently, it is possible to carry the wafer W both into the CVD chamber 13 and into the etching chamber 14 without causing any positional displacement. In other words, continuous processing is made possible without causing any positional displacement.

Further, in this embodiment, the absolute position of the X-Y jointed-arm robot 25 is detected. Therefore, it is possible to easily correct the positional displacement by reading the absolute position of the wafer W held by the tweezers 33.

In the explanation in this embodiment, as the X-Y jointed arm robot, that of 1-link type is taken as an example, but an X-Y jointed-arm robot of a different type from the 1-link type, for example, a 2-link type may be adopted.

### Second Embodiment

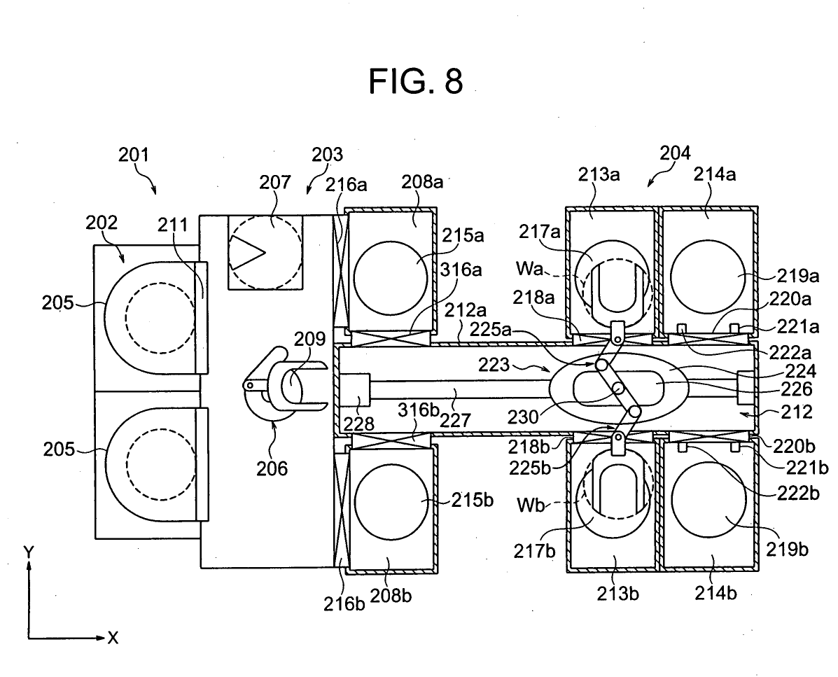

FIG. 8 is a plane view showing the configuration of a substrate processing apparatus according to a second embodiment of the present invention.

A cassette mounting table 202 and a transfer chamber 203 of a substrate processing apparatus 201 of this embodiment have the same configuration as the configuration of those in the above-described embodiment, and therefore, explanation of these portions will be omitted.

The substrate processing apparatus 201 is composed of the cassette mounting table 202, the transfer chamber 203, and a vacuum process section 204, which are arranged linearly in an X direction in the drawing.

Along a transfer path 212 of the vacuum process section 204, two load lock chambers 208a, 208b, two CVD chambers 213a, 213b, two etching chambers 214a, 214b are arranged in sequence from a transfer chamber 203 side, two respective chambers facing each other.

Sensors 221a and 222a are provided between a susceptor 219a and a gate valve 220a of the etching chamber 214a. Similarly, sensors 221b and 222b are provided between a susceptor 219b and a gate valve 220b of the etching chamber 214b.

In the transfer path 212, a wafer transfer mechanism 223 movable linearly along the X direction is provided. The wafer transfer mechanism 223 has a stage 224 movable linearly along the X direction. The stage 224 is configured to be moved by a motor 228 along a rail 227 in the X direction. Two robots 225a and 225b are attached on the stage 224. These two robots 225a and 225b share a single motor 230. This structure makes it possible to transfer two wafers W into the load lock chambers 208a, 208b or the like concurrently by the respective robots 225a and 225b.

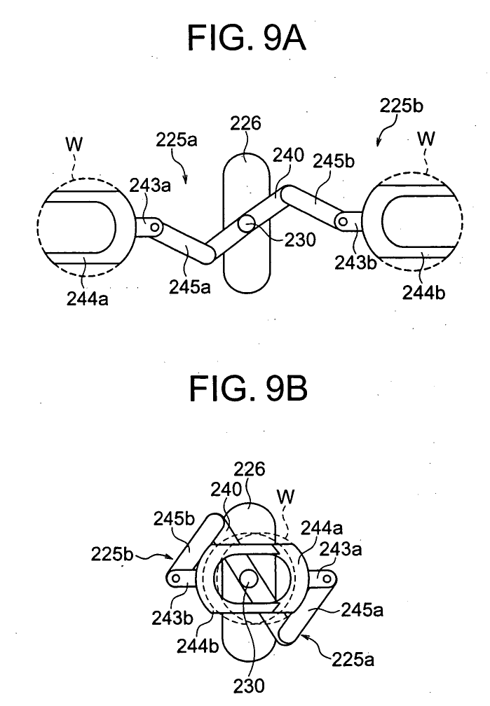

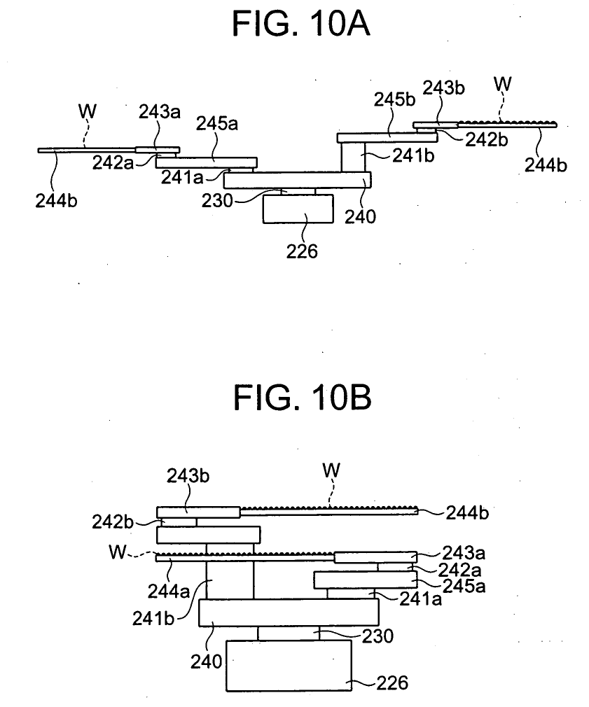

The wafer transfer mechanism 223 will be specifically explained. FIG. 9A and FIG. 10A are a plane view and a side view of the wafer transfer mechanism 223 with its arms extended, and FIG. 9B and FIG. 10B are a plane view and a side view thereof with its arms contracted. The motor 230 and a common arm 240 that are used in common for the two robots 225a and 225b are provided on a base 226. The common arm 240 is rotated by the rotation of the motor 230. Ends of first arms 245a, 245b are attached to both ends of the common arm 230 via shaft members 241a, 242a respectively. Ends of fixing members 243a, 243b are attached to the other ends of the first arms 245a, 245b via shaft members 242a, 242b. Tweezers 244a, 244b to hold wafers are fixed to the other ends of the fixing members 243a, 243b respectively. Since the shaft members 241a, 241b, 242a, 242b rotate in synchronization with the rotation of the motor 230, the two robots 225a and 225b perform extension/contraction operations synchronously in opposite directions to each other.

Next, the operation of the substrate processing apparatus 201 as configured above will be explained.

First, a shutter 211 opens, and a wafer transfer mechanism 206 accesses a cassette 205 to take out one wafer Wa. The wafer Wa that has been taken out is carried into a pre-alignment stage 207 to be pre-aligned. Thereafter, the wafer transfer mechanism 206 takes out the wafer Wa from the pre-alignment stage 207 to carry the wafer Wa into one of the load lock chambers, for example, the load lock chamber 208a. Similarly, one wafer Wb is carried into the load lock chamber 208b.

In the load lock chambers 208a (208b), the wafers Wa (Wb) are placed on mounting tables 215a (215b), and the wafers Wa (Wb) are kept on standby on the mounting tables 215a (215b). Thereafter, gate valves 216a (216b) are closed, and the inside of the load lock chambers 208a (208b) is brought into a vacuum state by a not-shown vacuum pump. When the vacuum state is obtained, gate valves 316a (316b) open, and the X-Y jointed-arm robots 225a (225b) take out the respective wafers Wa (Wb) placed on the mounting tables 215a (215b) concurrently to carry the wafers Wa (Wb) into the CVD chambers 213a (213b) respectively.

Then, when a CVD process is finished in the CVD chambers 213a (213b), gate valves 218a (218b) open. Next, the X-Y jointed-arm robots 225a (225b) access the CVD chambers 213a (213b) to take out the respective wafers Wa (Wb) concurrently. Further, the wafers Wa (Wb) that have been taken out are carried into the etching chambers 214a (214b) concurrently by the X-Y jointed-arm robots 225a (225b) respectively.

When the wafers Wa (Wb) are carried in, the positional displacement of the wafer Wa held by the X-Y jointed-arm robot 225a is first corrected in a similar manner to that explained in the above-described first embodiment. When the correction of the positional displacement of the wafer Wa is finished, the wafer Wa is lifted by not-shown lifter pins provided on the susceptor 219a. For example, while the wafer Wa is kept in a lifted state, the positional displacement of the wafer Wb is subsequently corrected by the other X-Y jointed-arm robot 225b.

First, the correction of the positional displacement of the wafer Wa causes the X-Y jointed-arm robots 225a and 225b to move as a unit. Therefore, in order to correct the positional displacement of the wafer Wb, the X-Y jointed-arm robots 225a and 225b are moved by an amount corresponding to the above movement in reverse directions in the X and Y axis directions. After the X-Y jointed-arm robots 225a and 225b are thus moved in the reverse directions, the positional displacement of the wafer Wb is corrected based on detection signals of sensors 221b and 222b in a similar manner as that in the above-described first embodiment. After the positional displacement of the wafer Wb is corrected, the wafer Wb is lifted by not-shown lifter pins provided on the susceptor 219b.

Thereafter, the X-Y jointed-arm robots 225a (225b) are made to retreat and the lifter pins in the respective etching chambers 214a (214b) are lowered concurrently. Thereafter, the gate valves 220a (220b) are closed and an etchback process is conducted. When the etchback process is finished, the gate valves 220a (220b) open, and the X-Y jointed-arm robots 225a (225b) access the etching chambers 214a (214b) to take out the wafers Wa (Wb) respectively. The wafers Wa (Wb) that have been taken out are further carried into the load lock chambers 208a (208b) to be placed on the mounting tables 215a (215b).

When the pressure inside the load lock chambers 208a (208b) is made slightly higher than the atmospheric pressure after the wafers Wa (Wb) are placed on the mounting tables 215a (215b), the gate valves 216a (216b) open so that the load lock chambers 208a (208b) are made open to the atmosphere.

Thereafter, the wafer transfer mechanism 206 takes out the wafers Wa (Wb) from the mounting tables 215a (215b) in the load lock chambers 208a (208b) to return them to the cassette 205.

As described above, in this embodiment, since it is possible to correct the positional displacement of the wafers W, the wafer transfer mechanism 223 is capable of carrying the wafers W into the respective etching chambers 214a, 214b without causing any positional displacement. Consequently, the wafers W can be placed on the susceptors 219a, 219b at proper positions. In other words, it is possible to continuously carry the wafers W into the CVD chambers 213a (213b) and the etching chambers 214a (214b) without causing any positional displacement.

Further, in the substrate processing apparatus 201 of this embodiment, the two X-Y jointed-arm robots 225a and 225b are provided to carry two wafers W into process chambers or the like facing each other, respectively, which realizes improvement in throughput. Further, the two wafers W are carried into the process chambers or the like concurrently, so that the process time for the respective wafers W can be easily made uniform.

The present invention is not to be limited to the embodiments explained above, but various changes may be made therein.

For example, the above-described first and second embodiments are configured such that the sensors are provided only in the etching chambers 14, 214a, 214b in FIG. 1 and FIG. 8. However, sensors may be provided also in the CVD chambers 13, 213a, 213b to correct the positional displacement. In this case, it is not necessary to provide the pre-alignment stages 7, 208.

The above-described embodiments are configured such that, for example, as shown in FIG. 1, the sensors 21, 22 are installed inside the etching chamber 14, but they may be installed outside the etching chamber 14 (on a transfer path 12 side). As for the CVD chambers, the sensors may be similarly installed outside the CVD chambers.

In the above-described first and second embodiments, both of the CVD chamber(s) and the etching chamber(s) are provided in line, but, the configuration of, for example, providing only the CVD chamber(s) or only the etching chamber(s) may be adopted.

The structures of the wafer transfer mechanisms 23, 223 are not limited to those in the above-described embodiments, but they may be transfer mechanisms of a linearly moving type. Further, the wafer transfer mechanism 223 in FIG. 8 has the single motor 230, but a motor may be provided independently for each of the robots 225a, 225b.

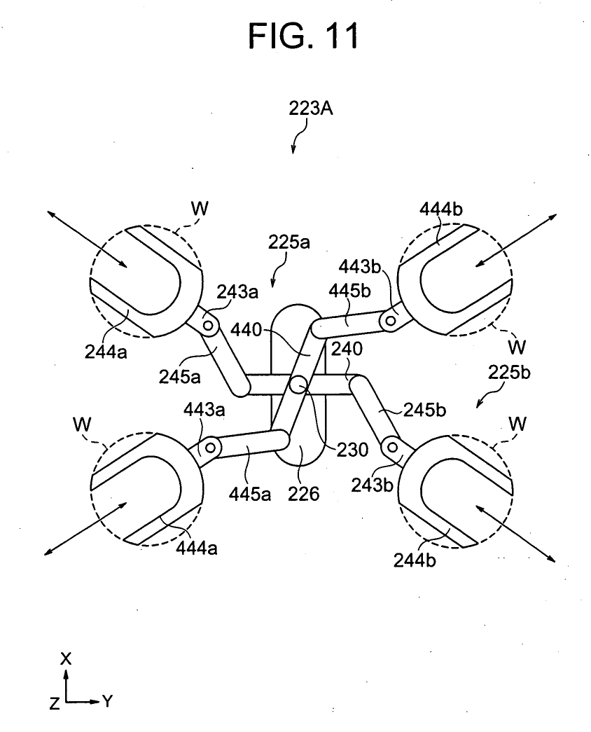

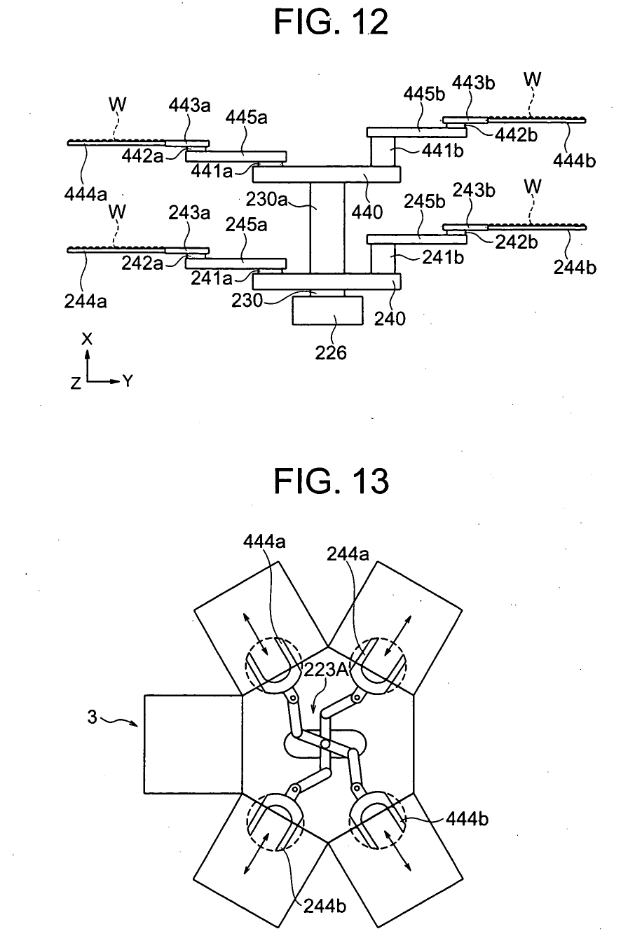

FIG. 11 and FIG. 12 are a plane view and a side view showing another embodiment of the wafer transfer mechanism. As shown in FIG. 11, a wafer transfer mechanism 223A of this embodiment includes: a base 226; tweezers 244a, 244b capable of holding wafers; fixing members 243a, 243b; first arms 245a, 245b; a common arm 240 coupling the tweezers 244a, 244b to each other via these fixing members 243a, 243b and first arms 245a, 245b and connected to the base 266; and a motor 230 configured to drive the common arm 240, thereby driving the tweezers 244a, 244b to move back and forth synchronously. The wafer transfer mechanism 223A further includes: tweezers 444a, 444b capable of holding wafers; fixing members 443a, 443b; first arms 445a, 445b; and a common arm 440 coupling the tweezers 444a, 444b to each other via these fixing members 443a, 443b and first arms 445a, 445b and connected to the base 266 via the motor 230. The tweezers 244a, 244b, 444a, 444b are driven by the single motor 230 to move in the arrow directions respectively and they are provided adjacent to one another.

As shown in FIG. 12, the wafer transfer mechanism 223A is constituted of two tiers of the wafer transfer mechanisms 223 shown in FIG. 9A and FIG. 9B that are tired in a Z axis direction. A shaft portion 230a is fixed to a rotation shaft of the motor 230, and an upper end and a lower end thereof are fixed to the common arms 440 and 240 respectively. With this structure, the shaft portion 230a is rotated in accordance with the rotation of the motor 230. The tweezers 244a, 244b and the tweezers 444a, 444b are configured to extend/contract at positions different in height in the Z direction. In the state in which the arms are contracted, the arms of the upper tier can contract similarly to the above-described embodiments, but in the arms of the lower tier, the tweezers 244a, 244b do not completely contract on the base 266 in order to avoid the interference between the shaft portion 230a and the tweezers 244a, 244b. In order to thus make the distance of back and forth movement of the tweezers different between the arms of the upper tier and the arms of the lower tier through the use of the single motor 230, for example, a gear mechanism may be provided in at least one of the pulleys A to D shown in FIG. 4 and so on or in other places. The wafer transfer mechanism 223A is substantially the same in length in the X and Y directions as and substantially double in height in the Z direction of that shown in FIG. 9A, FIG. 9B, FIG. 10A, and FIG. 10B.

As shown in FIG. 13, the tweezers 244a, 244b, 444a, 444b are configured to be capable of accessing the transfer chamber 3 and accessing the process chambers disposed around the wafer transfer mechanism 223A substantially concurrently.

With such a structure, since the tweezers 244a, 244b, 444a, 444b are capable of accessing the process chambers disposed around the wafer transfer mechanism 223A shown in FIG. 13 substantially concurrently, it is possible to enhance process efficiency.

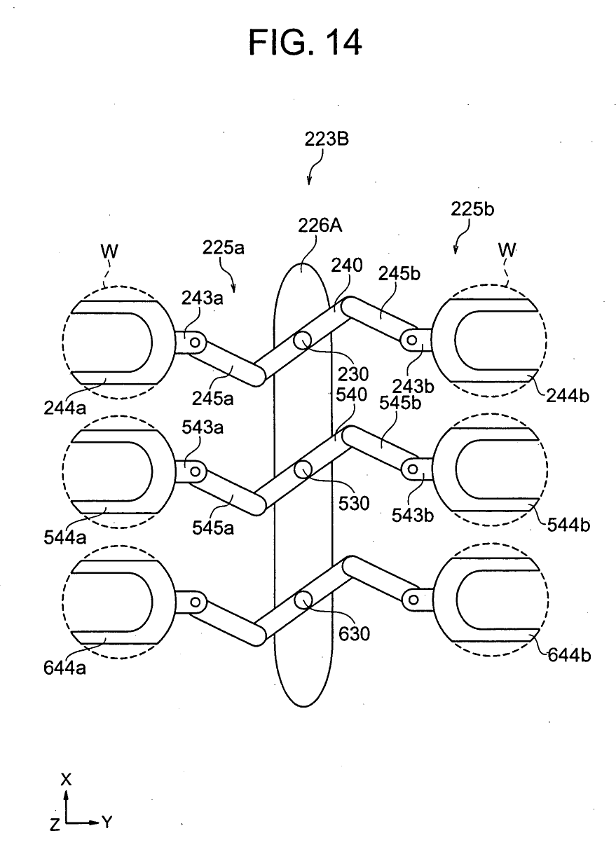

FIG. 14 is a plane view showing a wafer transfer mechanism according to still another embodiment. A wafer transfer mechanism 223B of this embodiment includes: a base 226A whose length in an X direction is larger than that of the base 226 of the above-described embodiment; and a plurality of, for example, three wafer transfer mechanism units that are arranged on the base 226A at predetermined intervals in the X direction. The wafer transfer mechanism units respectively include: tweezers 244a(b), 544a(b), 644a(b); fixing members 243a(b), 543a(b), 643a(b); first arms 245a(b), 545a(b), 645a(b); common arms 240, 540, 640 coupling the tweezers 244a(b), 544a(b), 644a(b) via these fixing members 243a(b), 543a(b), 643a(b) and first arms 245a(b), 545a(b), 645a(b) and connected to the base 266A; and motors 230, 530, 630 to drive the common arms 240, 540, 640. The interval in the X direction between the wafer transfer mechanism units is set to an interval such that the tweezers 244a(b), 544a(b), 644a(b) do not interfere with one another when the arms extend/contract.

The configuration described above enables substantially simultaneous access to the process chambers arranged in line in the X direction. Therefore, it is possible to enhance process efficiency.

1-11. (canceled)

12. A substrate processing apparatus, comprising:
a cassette mounting table for arranging a plurality of cassettes with wafers therein in a direction perpendicular to a wafer transfer direction;
a transfer chamber in which a linear transfer path is provided along said wafer transfer direction and which is maintained under vacuum conditions;
a plurality of first process chambers which are connected to the transfer chamber via first gate valves and disposed at both sides of the transfer chamber so as to be opposite to one another via the transfer chamber, and in which a first process is performed on wafers;
a plurality of second process chambers which are connected to the transfer chamber via second gate valves and disposed at both sides of the transfer chamber so as to be opposite to one another via the transfer chamber in the vicinity of the first process chambers, and in which a second process is performed on wafers that have finished the first process;
a plurality of load lock chambers which are connected to the transfer chamber via third gate valves and disposed at both sides of the transfer chamber so as to be opposite to one another via the transfer chamber, each load lock chamber having a fourth gave valve through which wafers are received from the cassette mounting table; and
a transfer mechanism which is provided in the transfer chamber so as to be connected to the linear transfer path under linearly moveable conditions and includes two jointed-arm mechanisms configured to receive wafers from the plurality of load lock chambers, translate the wafers along the linear transfer path, and carry the wafers simultaneously into and out of one or more of the first process chambers and the second process chambers in synchronization.

13. The substrate processing apparatus as set forth in claim 12,
wherein the two jointed-arm mechanisms share a common motor and a common arm;
wherein each of the two jointed-arm mechanisms includes a respective first arm which is connected at a first end to a corresponding end of the common arm, and a respective supporter which is connected to a second end of the respective first arm; and
wherein the two jointed-arm mechanisms are operated in synchronization by driving the common arm with the common motor.

14. The substrate processing apparatus as set forth in claim 12, further comprising:
a plurality of detecting mechanisms, each detecting mechanism having a photosensor stationed inside one of the second process chambers along a carry-in route for a wafer to be conveyed to a table in one of said second process chambers via a second gate valve thereof and, each detecting mechanism being configured to detect a relative position between the wafer carried by the transfer mechanism and the table; and
a correcting mechanism which is configured to correct the positional displacement of a wafer based on a relative position detected by one of the detecting mechanisms.
